(19) United States
(12) Patent Application Publication
(10) Pub. No.: US 2025/0087610 A1
(43) Pub. Date: Mar. 13, 2025

(54) ELECTRONIC CHIP WITH CONNECTING PILLARS FOR SINTERING ASSEMBLY

(71) Applicants: Commissariat à I'Énergie Atomique et aux Énergies Alternatives, Paris (FR); Centre National de la Recherche Scientifique, Paris Cedex 16 (FR); Université de Bordeaux, Bordeaux Cedex (FR); Institut Polytechnique de Bordeaux, Talence (FR)

(72) Inventors: Céline Feautrier, Grenoble (FR); Jean-Charles Souriau, Grenoble (FR); Julie Gougeon, Grenoble (FR); Mona Treguer-Delapierre, Grenoble (FR)

(73) Assignees: Commissariat à I'Énergie Atomique et aux Énergies Alternatives, Paris (FR); Centre National de la Recherche Scientifique, Paris (FR); Université de Bordeaux 1, Bordeaux Cedex (FR); Institut Polytechnique de Bordeaux, Talence (FR)

(21) Appl. No.: 18/825,283

(22) Filed: Sep. 5, 2024

(30) Foreign Application Priority Data
Sep. 8, 2023 (FR) 2309488

(51) Int. Cl. H01L 23/00

(52) U.S. Cl. CPC H01L 24/11; H01L 24/81; H01L 2224/1147; H01L 2224/11903; H01L 2224/8102; H01L 2224/8184

(57) ABSTRACT

An electronic chip including a support and connection pillars, each connection pillar including a trunk including an end portion and an intermediate portion coupling the end portion to the support, and including a collar at the junction between the end portion and the intermediate portion.

### CROSS REFERENCE TO RELATED APPLICATIONS

This application claims priority to French application number 2309488, filed Sep. 8, 2023. The content of this application is incorporated herein by reference in its entirety.

### TECHNICAL FIELD

The present description relates to the field of electrical connection between an electronic chip and a package or between two electronic chips, and more particularly to connection pillars of the electronic chip.

### BACKGROUND ART

In an electronic chip, connections are made by inner interconnection networks. To connect an integrated circuit chip to an outer element, these interconnection networks are connected to pillars, generally located on one face of the chip. In this way, it is possible to contact the pillars with conductive areas or connection tracks located on this other element. The element may correspond to a substrate, also known as a package, particularly in the field of power electronics, such as a printed circuit. The element could also correspond to another electronic chip.

An example of a method of assembling an electronic chip to another electronic chip or package comprises forming a block of sinter paste on each pillar, depositing the electronic chip on the other electronic chip or package, and sintering the sinter paste. In some applications, sintering is carried out at a temperature below 200° C., and without exerting pressure on the electronic chip. For such applications, the step of depositing the electronic chip on the other electronic chip or the package is carried out before drying the sinter paste.

### SUMMARY OF INVENTION

One embodiment overcomes some or all of the drawbacks of electronic chips comprising known connection pillars.

One embodiment provides an electronic chip comprising a support and connection pillars, each connection pillar comprising a trunk including an end portion and an intermediate portion coupling the end portion to the support and comprising a collar at the junction between the end portion and the intermediate portion.

According to one embodiment, the height of the end portion is between 10 μm and 100 μm.

According to one embodiment, the height of the intermediate portion is between 10 μm and 100 μm.

According to one embodiment, the difference between the maximum lateral dimension of the collar and the minimum lateral dimension of the end portion is between 1 μm and 7 μm.

According to one embodiment, the end portion comprises an end face on the side opposite the intermediate portion.

According to one embodiment, the end portion has a flared shape on the end-face side.

According to one embodiment, the connection pillar comprises a finishing layer covering the end face.

According to one embodiment, the trunk is made of copper.

One embodiment also provides a method of assembling an electronic chip as defined above to another electronic chip or to a package, comprising penetrating the connection pillars into a layer of sinter paste at least up to the collar of each connection pillar, removing the connection pillars from the layer of sinter paste, a block of sinter paste remaining attached to each connection pillar, depositing the electronic chip on the other electronic chip or on the package, and heating to obtain sintering of the blocks of sinter paste.

One embodiment also provides a method of manufacturing an electronic chip as defined above, comprising forming a first photosensitive resin mask comprising, for each connection pillar, a first through opening, depositing the material making up the trunk in the first through openings, forming a second photosensitive resin mask comprising a second through opening in the extension of each first through opening, and depositing the material making up the trunk in the second through openings.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 schematically illustrates an embodiment of a connection pillar of a chip;

FIG. 2, FIG. 3, and FIG. 4 schematically illustrate each another embodiment of a connection pillar;

FIG. 5 and FIG. 6 are each an image obtained by scanning electron microscopy of the connection pillar shown in FIG. 1;

FIG. 7, FIG. 8, FIG. 9, and FIG. 10 illustrate structures obtained at successive steps of an embodiment of a method of assembling the chip shown in FIG. 1 to another chip or to a package;

FIG. 11 is an image obtained by scanning electron microscopy of the connection pillar shown in FIG. 1 at the step of the assembly method illustrated in FIG. 9;

FIG. 12 is an image obtained by scanning electron microscopy of a section of the structure obtained at the step of the assembly method illustrated in FIG. 10; and

FIG. 13, FIG. 14, FIG. 15, FIG. 16, FIG. 17, FIG. 18, FIG. 19, and FIG. 20 illustrate structures obtained at successive steps of a method of manufacturing the chip shown in FIG. 1.

### DESCRIPTION OF EMBODIMENTS

Like features have been designated by like references in the various Figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the various components of the chips, as well as the inner connections of the chips, are not described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Furthermore, the terms “insulator” and “conductor” are taken to mean “electrically insulating” and “electrically conductive” respectively.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the Figures, or to an electronic circuit as orientated during normal use.

Unless specified otherwise, the expressions “around”, “approximately”, “substantially” and “in the order of” signify within 10%, and preferably within 5%.

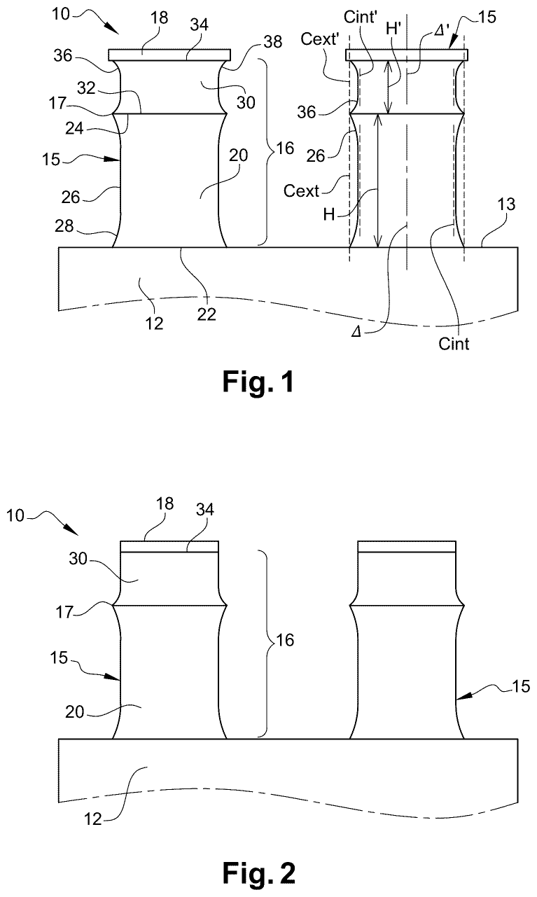

FIG. 1 is a schematic, partial side view of an embodiment of an electronic chip 10 that is to be connected to a package or another electronic chip, not shown. The chip 10 comprises connection pillars 15, also known as connection pads, made of a conductive material. Although two connection pillars 15 are illustrated in FIG. 1, the chip 10 comprises as many connection pillars 15 as there are connections to be made (depending on the intended application, only two, several tens or even several thousands of connection pillars 15 may be present). The chip 10 comprises, for example, a support 12 with a face 13 on which the electrical connections to the outside of the chip 10 are made. By way of example, support 12 comprises a substrate, for example in silicon, covered with an interconnection structure comprising conductive elements not shown, for example vias and metallization. Each connection pillar 15, for example, is electrically connected to such conductive elements.

Each pillar 15 comprises a trunk 16 having an intermediate portion 20 and an end portion 30. The intermediate portion 20 is located between the support 10 and the end portion 30. The pillar 15 comprises a collar 17 at the junction between the intermediate portion 20 and the end portion 30. The intermediate portion 20 comprises a base 22, a coupling face 24 opposite the base 22, and a side wall 26 coupling the base 22 to the coupling face 24. The end portion 30 comprises a coupling face 32, an end face 34 opposite the coupling face 32, and a side wall 36 coupling the coupling face 32 to the end face 34. The base 22 of the intermediate portion 20 is in direct physical contact with the support 12. The coupling face 24 of the intermediate portion 20 is coincident with the coupling face 32 of the end portion 30. According to one embodiment, the side wall 36 of the end portion 30 further comprises a flared part 38 on the side of the top face 32. According to one embodiment, the side wall 26 of intermediate portion 20 further comprises a flared part 28 on the side of base 22.

The side wall 26 of intermediate portion 20 is contained between a circular-based inner cylinder Cint of axis Δ and a circular-based outer cylinder Cext of axis Δ, and is in contact with inner cylinder Cint and outer cylinder Cext. According to one embodiment, the coupling face 24 of the intermediate portion 20 is substantially perpendicular to the axis Δ. The height H of the intermediate portion 20, measured along the axis Δ, is between 10 μm and 100 μm, and is preferably equal to approximately 50 μm. The diameter of the inner cylinder Cint is between 10 μm and 3 mm, and is preferably equal to about 50 μm. The difference between the radius of the outer cylinder Cext and the radius of the inner cylinder Cint is between 1 μm and 100 μm, preferably between 1 μm and 7 μm. According to one embodiment, the pitch between the axes A of adjacent pillars 15 is between 20 μm and 7 mm, and is preferably equal to approximately 100 μm. According to one embodiment, except in the vicinity of the base 22 and coupling face 24, intermediate portion 20 is essentially cylindrical in shape with a circular base.

The side wall 36 of the end portion 30 is contained between a circular-based inner cylinder Cint′ of axis Δ′ and a circular-based outer cylinder Cext′ of axis Δ′, and is in contact with the inner cylinder Cint′ and the outer cylinder Cext′. The axis Δ is parallel to the axis Δ′. According to one embodiment, the axis Δ′ is coincident with the axis Δ. However, the axis Δ′ can be offset from the axis Δ. The offset between the axis Δ′ and the axis Δ can be between 0 μm and 6 μm. According to one embodiment, the coupling face 32 of the end portion 30 is substantially perpendicular to the axis Δ. According to one embodiment, the end face 34 of the end portion 30 is substantially perpendicular to the axis Δ. The height H′ of the end portion 30 measured along the axis Δ′ is between 10 μm and 100 μm, preferably between 10 μm and 40 μm, and is for example equal to approximately 20 μm. The difference between the radius of the outer cylinder Cext′ and the radius of the inner cylinder Cint′ is between 1 μm and 7 μm, preferably between 1 μm and 4 μm. According to one embodiment, except in the vicinity of coupling face 32 and end face 34, end portion 30 is essentially cylindrical in shape with a circular base.

Trunk 16 is made of metal, for example copper, nickel, silver, gold or an alloy of these metals.

According to one embodiment, the pillar 15 further comprises a finishing layer 18 covering the end face 34 of the end portion 30 of the trunk 16. The thickness of the finishing layer 18 is between 10 nm and 1,000 nm. Finishing layer 18 is made of a conductive material that improves the adhesion of the sinter paste. For example, finishing layer 18 is made of a metal, in particular gold or silver, and optionally comprises a bonding and/or barrier layer(s), comprising for example platinum (Pt), palladium (Pd), nickel (Ni), titanium (Ti), chromium (Cr), and/or tantalum (Ta), between the material of trunk 16 and the material of the sinter paste subsequently deposited on pillar 15. The finishing layer 18 also allows oxidation of the end face 34 of the pillar 15 to be prevented in the case where the assembly method is not carried out in a neutral or reducing atmosphere.

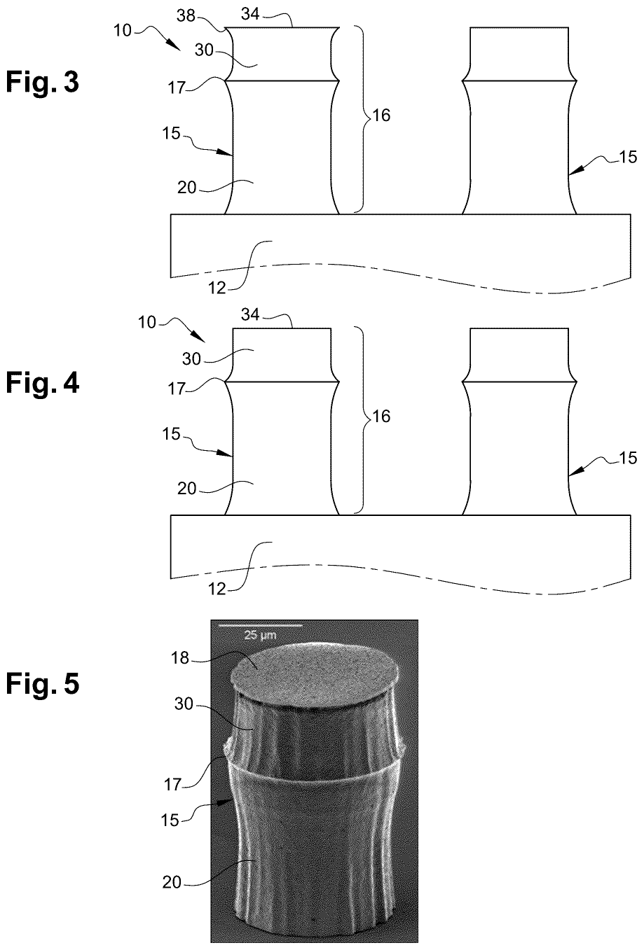

FIG. 2 is a partial schematic side view of another embodiment of chip 10. Each pillar 15 of the chip 10 illustrated in FIG. 2 comprises all the elements of the pillar 15 of the chip 10 illustrated in FIG. 1, with the difference that the end portion 30 of the trunk 16 does not comprise a flared part 38 on the side of the end face 34.

FIG. 3 is a partial schematic side view of another embodiment of chip 10. Each pillar 15 of the chip 10 illustrated in FIG. 3 comprises all the elements of the pillar 15 of the chip 10 illustrated in FIG. 1, with the difference that the finishing layer 18 is not present.

FIG. 4 is a partial schematic side view of another embodiment of chip 10. Each pillar 15 of the chip 10 illustrated in FIG. 4 comprises all the elements of the pillar 15 of the chip 10 illustrated in FIG. 2, with the difference that the finishing layer 18 is not present.

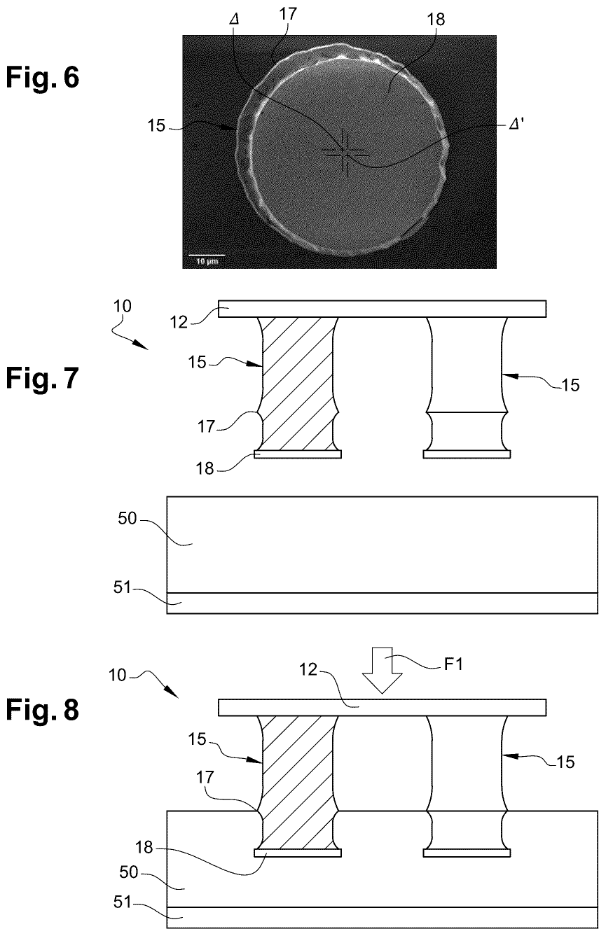

FIG. 5 is an image obtained by scanning electron microscope in perspective view of a pillar 15 according to one embodiment as described above in relation to FIG. 1.

FIG. 6 is an image obtained by scanning electron microscope of the pillar 15 shown in FIG. 5 viewed along the axis Δ from the side of the bonding layer 18. In this example, the axis Δ is offset from the axis Δ′.

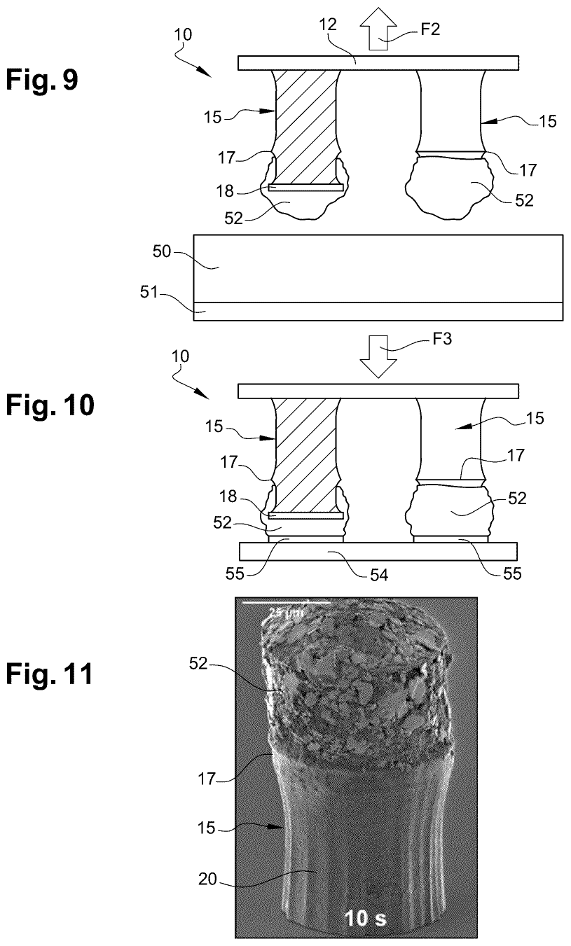

FIGS. 7 to 10 each comprise a left-hand cross-sectional view and a right-hand side view of the structure obtained in successive steps of an embodiment of a method of assembling chip 10 to another chip or to a package.

FIG. 7 illustrates the structure obtained after forming a layer 50 of sinter paste in a cavity 52. The thickness of the paste layer 50 is greater than the height H′ of the end portion 30 of the pillar 15. The thickness of the paste layer 50 is between 20 μm and 200 μm, and is, for example, equal to approximately 50 μm.

The chip 10 is positioned above the paste layer 50 in a vertical direction and at a distance from the paste layer 50. The finishing layer 18 of each pillar 15 is oriented towards the paste layer 50. The dynamic viscosity of the paste layer 50 is between 20 Pa·s and 60 Pa·s. The thixotropy of the paste layer 50 is between 3 and 7. Paste layer 50 is made of a sinterable material. In particular, paste layer 50 comprises an active filler comprising particles of a metallic material, for example silver, copper, or an alloy of silver and copper. The active filler could also comprise gold and other additives, such as polymers and/or ceramics, which do not participate in the sintering process but facilitate the methods for implementing the sinter paste. The proportion of active filler in the paste layer 50 is between 60% and 97% by weight.

FIG. 8 illustrates the structure obtained after the chip 10 has been pressed into the paste layer 50 until at least the entire end portion 30 of each pillar 15 has penetrated the paste layer 50. According to one embodiment, the chip 10 is moved relative to the paste layer 50 by means of a handling tool, not shown, for example in a vertical movement (arrow F1). According to one embodiment, chip 10 is set in motion at a given initial speed. According to one embodiment, a penetration resistance effort of the chip 10 into the paste layer 50 is measured, and the movement of the chip 10 is stopped when the resistance effort exceeds a threshold.

FIG. 9 illustrates the structure obtained after removing the chip 10 (arrow F2) from the paste layer 50 until each pillar 15 is completely outside the paste layer 50. A paste block 52 remains attached to each pillar 15. The finishing layer 18 is made of a material that favors adhesion of the paste block 52. The inventors have shown that the presence of collar 17 causes that the volume of paste block 52 remaining attached to pillar 15 is greater than in the case where collar 17 is not present. The minimum thickness of the paste block 52 between each pillar 15 and the other chip/package 54 is greater than 4 μm, preferably between 7 μm and 15 μm. A high minimum thickness may be achieved due to the large volume of paste block 52 carried by each pillar 15.

FIG. 10 illustrates the structure obtained after depositing the chip 10 on another chip or package 54 in such a way that each pillar 15 faces a conductive track 55 of the other chip or package 54, with the paste block 52 contacting the conductive track 55. According to one embodiment, the chip 10 is placed on the other chip/package 54 (arrow F3), that causes the paste blocks 52 to be deformed only by the weight of the chip 10. According to one embodiment, chip 10 is moved towards the other chip/package 54 by a handling tool, not shown, until a criterion is reached, for example until the distance between the support 12 of chip 10 and the other chip/package 54 reaches a given distance, or until the movement resistance effort of chip 10 exceeds a threshold. The deformation of the paste blocks 52 is then also caused by the action exerted by the handling tool on the chip 10. The minimum thickness of the paste block 52 between each pillar 15 and the other chip/package 54 after removing the chip 10 from the paste layer 50 allows to ensure that sinter paste remains present between each pillar 15 and the conductive track 55 despite any height inhomogeneity of the pillars present on the chip 10 and/or any curvature of the chip 10.

The method goes on with a heating step that causes the paste block 52 to sinter, and the chip 10 to adhere to the chip or package 54, for example at a temperature below 200° C. According to one embodiment, during the heating step, no pressure is exerted on chip 10, or only a pressure of less than 1 MPa. According to one embodiment, the heating temperature is between 130° C. and 300° C., preferably between 150° C. and 250° C.

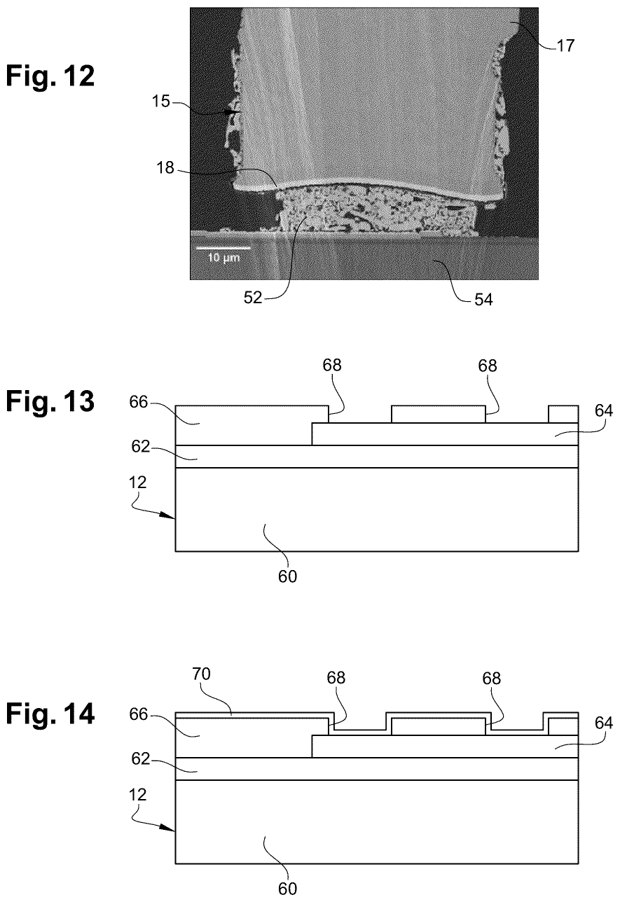

FIG. 11 is an image obtained by scanning electron microscopy in perspective view of a pillar 15 at the step previously described in relation to FIG. 9, i.e. after removing chip 10 from paste layer 50. The intermediate portion 20 is at the bottom of the image. The paste block 52 completely covers the end portion of pillar 15.

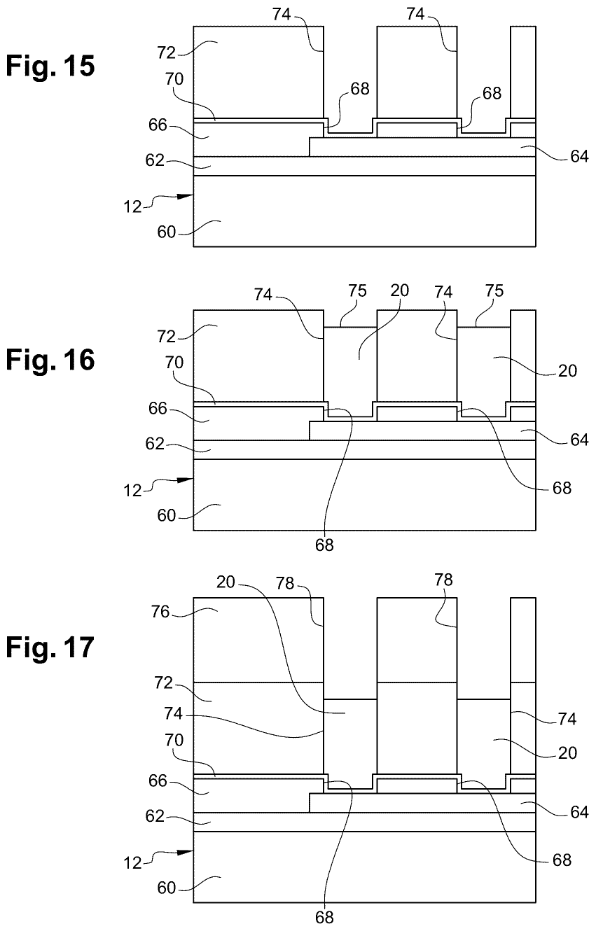

FIG. 12 is an image obtained by scanning electron microscopy of a section of a pillar 15 at the step previously described in relation to FIG. 10, i.e. after depositing the chip 10 on the other chip or package 54.

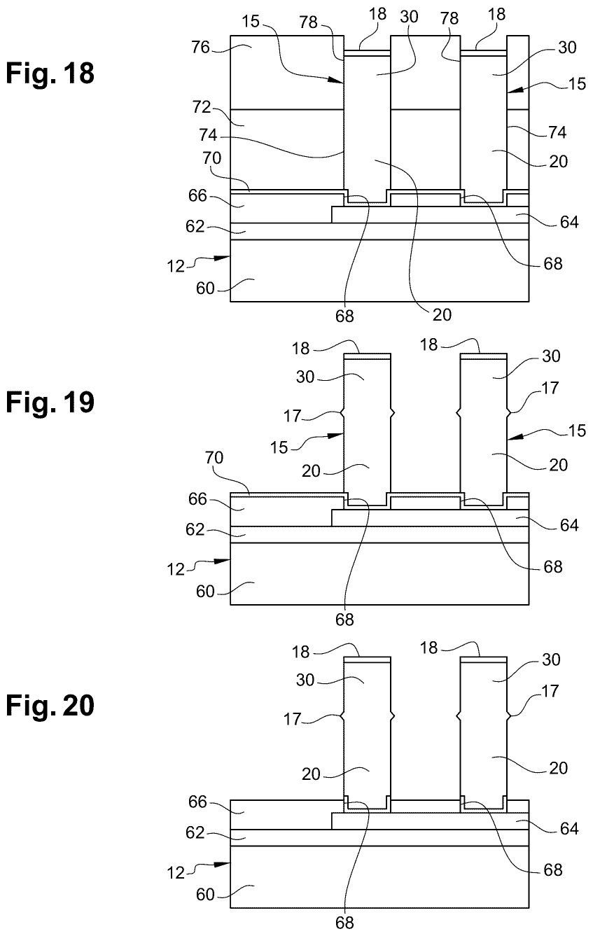

FIGS. 13 to 20 are schematic partial sectional views of the structures obtained at successive steps of an embodiment of a method of manufacturing the chip 10 shown in FIG. 1.

FIG. 13 illustrates the structure obtained after forming an interconnection structure on support 12. According to one embodiment, support 12 comprises a substrate 60, for example a semiconductor substrate, covered by an insulating layer 62. A conductive track 64 extends over the insulating layer 62. The conductive track 64 could be connected to regions of the semiconductor substrate 60 by conductive vias not shown. An insulating layer 66 extends over the conductive track 64 and the insulating layer 66. For each connection pillar to be made, a through opening 68 extends through the entire thickness of the insulating layer 66, each through opening 68 exposing a part of the conductive track 64. The interconnection structure depends on the desired connections of the connection pillars. In the example illustrated in FIG. 13, the two connection pillars to be formed are connected to the conductive track 64.

Substrate 60 may, for example, be made of silicon, silicon carbide (SIC), III-V compounds, in particular gallium nitride (GaN), or diamond. Substrate 60 could have a single-layer or multi-layer structure, for example of the Silicon-On-Insulator (SOI) type. According to one embodiment, the thickness of substrate 60 is between 100 μm and 900 μm, for example 200 μm. The insulating layer 62 is, for example, a silicon oxide layer. According to one embodiment, the thickness of the insulating layer 62 is between 100 nm and 2 μm, and is for example equal to 200 nm. The conductive track 64 comprises, for example, a stack of metal layers. According to one embodiment, the metal track 64 could be performed by whole-wafer depositing metal layers and etching the metal layers to form the metal track 64. According to one embodiment, the thickness of the metal track 64 is between 200 nm and 2 μm, and is for example equal to 500 nm. The metal layers of the metal track are made, for example, of materials selected from copper, a copper alloy, titanium, a titanium alloy, titanium nitride, platinum and a platinum alloy.

FIG. 14 illustrates the structure obtained after forming a metal layer 70 over the entire structure obtained in the previous step. In particular, metal layer 70 extends into the bottom of each opening 68 in contact with metal track 64. According to one embodiment, the thickness of metal layer 70 is between 10 nm and 1 μm. Metal layer 70 could comprise a titanium or chromium layer, acting as an adhesion layer, and a copper layer acting as a primer layer for the subsequent formation of pillar 15.

FIG. 15 illustrates the structure obtained after forming a first photosensitive resin mask 72 on the metal layer 70 comprising through openings 74, each through opening 74 exposing the metal layer 70 in one of the openings 68. The through openings 74 could be performed by photolithography steps. The height of the first mask 72 is equal to the height H of the intermediate portion 20 of each pillar 15.

FIG. 16 illustrates the structure obtained after forming at least part of the intermediate portion 20 of each pillar 15. According to one embodiment, the part of the intermediate portion 20 of each pillar 15 may not completely fill the corresponding opening 74. The material making up each pillar 15 could be deposited by electroplating. The free face 75 of the part of the intermediate portion 20 may be set back from the upper face of the first mask 72, as illustrated in FIG. 16.

FIG. 17 illustrates the structure obtained after forming a second mask 76 of photosensitive resin on the first mask 72, comprising through openings 78, each through opening 78 exposing one of the openings 74 of the first mask 72. The second mask 76 can be made of the same photosensitive resin as that used to form the first mask 72, and the through openings 78 could be performed by photolithography steps. The height of the second resin mask 78 is greater than or equal to the height H′ of the end portion 30 of each pillar 15.

FIG. 18 illustrates the structure obtained after forming the remaining of the intermediate portion 20 of each pillar 15, forming the end portion 30 of each pillar 15, and forming the finishing layer 18 of each pillar 15. The material making up the trunk 16 of each pillar 15 could be deposited by electroplating.

FIG. 19 illustrates the structure obtained after removing the second mask 76 and removing the first mask 72. This could be performed by dissolving the resin in a solvent or by a dry etching step. The inventors have shown that each pillar 15 obtained comprises the collar 17 located at the interface between the first mask 72 and the second mask 76.

FIG. 20 illustrates the structure obtained after removing the metal layer 70 around the pillars 15.

In the embodiment previously described in relation to FIGS. 13 to 20, forming the trunk 16 of each pillar 15 comprises two electrodeposition steps, the first deposition step comprising partial filling of the openings 74 of the first mask 72, and the second deposition step comprising completion of filling of the openings 74 of the first mask 72, and total or partial filling of the openings 78 of the second mask 76. Alternatively, forming the trunk 16 of each pillar 15 comprises a single electrodeposition step comprising the total filling of the openings 74 of the first mask 72, and the total or partial filling of the openings 78 of the second mask 76. Such an alternative could be implemented when the form factor of the openings 74 and 78 is compatible with the electroplating method.

Various embodiments and variants have been described. Those skilled in the art will understand that certain features of these embodiments can be combined and other variants will readily occur to those skilled in the art. Finally, the practical implementation of the embodiments and variants described herein is within the capabilities of those skilled in the art based on the functional description provided hereinabove.

1. A method of manufacturing an electronic chip comprising a support and connection pillars, each connection pillar comprising a trunk comprising an end portion and an intermediate portion coupling the end portion to the support and comprising a collar at the junction between the end portion and the intermediate portion, the method comprising forming a first mask of photosensitive resin comprising, for each connection pillar, a first through opening, depositing the material making up the trunk in the first through openings, forming a second mask of photosensitive resin comprising a second through opening in the extension of each first through opening, and depositing the material making up the trunk in the second through openings.

2. The method of manufacturing according to claim 1, wherein the height of the end portion is between 10 μm and 100 μm.

3. The method of manufacturing according to claim 1, wherein the height of the intermediate portion is between 10 μm and 100 μm.

4. The method of manufacturing according to claim 1, wherein the difference between the maximum lateral dimension of the collar and the minimum lateral dimension of the end portion is between 1 μm and 7 μm.

5. The method of manufacturing according to claim 1, wherein the end portion comprises an end face on the side opposite the intermediate portion.

6. The method of manufacturing according to claim 5, wherein the end portion has a flared shape on the side of the end face.

7. The method of manufacturing according to claim 5, wherein the connection pillar comprises a finishing layer covering the end face.

8. The method of manufacturing according to claim 1, wherein the trunk is made of copper.

9. A method of assembling an electronic chip manufactured according to the method of manufacturing according to claim 1 to another electronic chip or to a package, comprising penetrating the connection pillars into a layer of sinter paste at least up to the collar of each connection pillar, removing the connection pillars from the layer of sinter paste, a block of sinter paste remaining attached to each connection pillar at least over the height of the end portion, preferably over a height equal to 50 μm, depositing the electronic chip on the other electronic chip or on the package, and heating to obtain sintering of the blocks of sinter paste.

10. The method of assembling according to claim 9, wherein, during heating to obtain sintering of the blocks of sinter paste, there is no pressure exerted on the electronic chip.

11. The method of assembling according to claim 9, wherein the amount of paste to be sintered after bonding, between each connection pillar and the other chip or package, is greater than 4 μm, preferably between 7 μm and 15 μm.
